(19) United States
(12) Patent Application Publication
(10) Pub. No.: US 2015/0084601 A1
(43) Pub. Date: Mar. 26, 2015

(54) DEVICE FOR DETERMINING A PROPERTY OF A BATTERY AND METHOD FOR OPERATING SUCH A DEVICE

(71) Applicant: COMMISSARIAT A L'ENERGIE ATOMIQUE ET AUX ENERGIES ALTERNATIVES, Paris (FR)

(72) Inventors: Sothun Eric Hing, Chambery (FR); Duy Long Ha, Chambery Le Vieux (FR)

(73) Assignee: COMMISSARIAT A L'ENERGIE ATOMIQUE ET AUX ENERGIES ALTERNATIVES, Paris (FR)

(21) Appl. No.: 14/394,857

(22) PCT Filed: Apr. 19, 2013
(86) PCT No.: PCT/EP2013/058223

§ 371 Date: Oct. 16, 2014

(30) Foreign Application Priority Data
Apr. 19, 2012 (FR) 1253609

(51) Int. Cl. G01R 31/36; B60L 11/18

(52) U.S. Cl. CPC G01R 31/3679; G01R 31/3606; B60L 11/1809; B60L 11/1861
USPC 320/132

(57) ABSTRACT

Method of operation of a device for determining a feature of a battery from among the state of charge of the battery, the state of health of the battery and the capacity of the battery, the device comprising a man-machine interface, the method comprising receiving a request to determine an actual value of the feature of a battery, determining, by interrogating a user via the man-machine interface, the next date at which a consuming device will need energy from the battery, verifying that it is possible to determine the actual value of the feature of the battery by the next date, and if such is the case, determining the actual value of the feature of the battery by carrying out a phase of charging and/or discharging of the battery.

The present invention relates to a method of operation of a device for determining a feature of an electrical energy storage accumulator battery. The invention also relates to a device implementing such a method of operation. The invention further relates to a system comprising such a device and a battery.

Customarily, batteries are used under charge and under discharge throughout their life according to values of parameters or features defined or assumed valid when they are put into service. At least part of the management of the battery relies on the values of these parameters or features.

However, the values of these parameters can evolve throughout the life of the battery or as it ages.

The management of the battery whatever its use (portable apparatus, electric car, etc.) is an indispensable element for optimizing its operation, its lifetime and its safety. Management of battery operation is also indispensable for providing users with reliable information such as in particular the state of charge SOC, the state of health SOH, the state of safety SOS and the remaining range achievable before top-up. The state of charge SOC (or capacity remaining in %) is the ratio of the capacity remaining Cr at a given instant to the available total actual capacity Cref. Note that the available total actual capacity Cref evolves negatively in the course of the service life of the accumulator. This is due to the wear of the battery in the course of use. The state of health SOH (or state of wear in %) is the ratio of the available total actual capacity Cref at a given instant to the initial available total actual capacity Cref0 measured at the start of the battery's usage life.

However, in the actual case of the use of the battery for diverse applications, the values of Cref and of Cr determined by the system for managing the operation of the battery may be erroneous on account of various reasons:
use of the battery under partial discharge, that is to say absence of complete discharge during the life of the battery;
use under partial charge, that is to say absence of complete charge during the life of the battery;
voltage and current measurement error, giving rise to an aggregate error in the values determined of Cr and Cref during use;
aging and calendar self-discharging;
crashing of the battery operation management system.

Consequently, the SOC and SOH values are impacted by the problems mentioned hereinabove, may be erroneous and far removed from the actual values.

This results in inappropriate management of battery operation, this being undesirable for the user.

The aim of the invention is to provide a method of operation of a device for determining a feature of a battery making it possible to remedy the problems mentioned above and improving the known prior art methods of operation. In particular, the invention proposes a simple and inexpensive method of operation making it possible to prevent erroneous values from being taken into account when managing the operation of the battery.

According to the invention, the method governs the operation of a device for determining a feature of a battery from among the state of charge of the battery, the state of health of the battery and the capacity of the battery. The device comprises a man-machine interface. The method comprises the following steps:
Receiving a request to determine an actual value of the said feature of a battery,
Determining, by interrogating a user via the man-machine interface, the next date at which a consuming device will need energy from the battery,
Verifying that it is possible to determine the actual value of the said feature of the battery ahead of the next date,
If such is the case, determining the actual value of the said feature of the battery by carrying out a phase of charging and/or discharging of the battery.

The feature can be the state of health of the battery or the capacity of the battery, at least one value of the said feature can be saved in a memory and, after determination of the actual value of the feature, this actual value can be recorded in the said memory.

The step of determining the actual value of the feature of the battery can comprise a phase of discharging of the battery, in particular a phase of complete or partial discharging of the battery, and then a phase of charging of the battery, in particular a phase of complete or partial charging of the battery.

The step of determining the actual value of the feature of the battery can comprise a phase of complete charging of the battery.

It is possible to determine the intensity of the battery charging current throughout the battery charging phase and it is possible to use this intensity to determine the level of the charge of the battery at the end of the charging phase.

The step of determining the actual value of the feature of the battery can comprise a phase of complete discharging of the battery.

It is possible to determine the intensity of the battery discharge current throughout the battery discharging phase and it is possible to use this intensity to determine the level of the charge of the battery at the end of the discharging phase.

The step of receiving a request to determine an actual value of the feature of the battery can comprise the detection of a deadline of a time delay triggered during a previous determination step and/or a detection of a wish for determination expressed by the user of the device.

The step of verifying that it is possible to determine the actual value of the feature of the battery by the next date at which a consuming device will need energy from the battery can comprise a validation confirming that the device is not forecast to use energy from the battery for a duration at least equal to the duration of the step of determining the actual value of the feature of the battery.

The energy arising from the battery during the discharging of the battery can be:
used to recharge at least one other battery; and/or
used in a residence to which the device is electrically connected; and/or
fed into an electrical network, in particular the commercial electrical network.

The invention also pertains to a data recording medium readable by a calculator on which is recorded a computer program comprising software means for implementing the steps of the above-defined method.

According to the invention, the device for determining a feature of a battery from among the state of charge of the battery, the state of health of the battery and the capacity of the battery, the device comprising a man-machine interface comprises hardware and/or software elements for implementing the steps of the above-defined method.

The hardware and/or software elements can comprise:
An element for receiving a request to determine an actual value of the feature of a battery,
An element for determining, by interrogating a user, the next date at which a consuming device will need energy from the battery,
An element for verifying that it is possible to determine the actual value of the feature of the battery ahead of the next date,
An element for determining the actual value of the feature of the battery by carrying out a phase of charging and/or discharging of the battery.

According to the invention, a system, in particular an automotive vehicle, comprises an above-defined device, a battery and a consuming device.

The invention also pertains to an intelligent method comprising a means of computerized program code suitable for the realization of the steps of the above-defined method, when the program is executed on calculator or automaton.

The appended drawings represent, by way of example, an embodiment of a method of operation according to the invention and an embodiment of a device according to the invention.

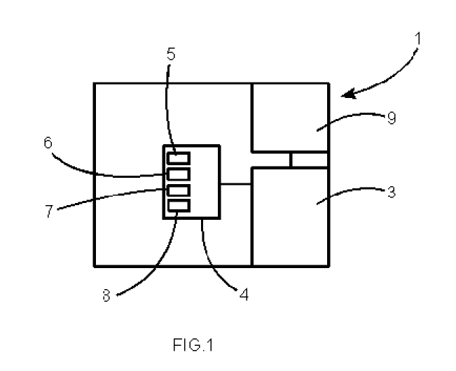

FIG. 1 is a diagram representing an embodiment of a system according to the invention.

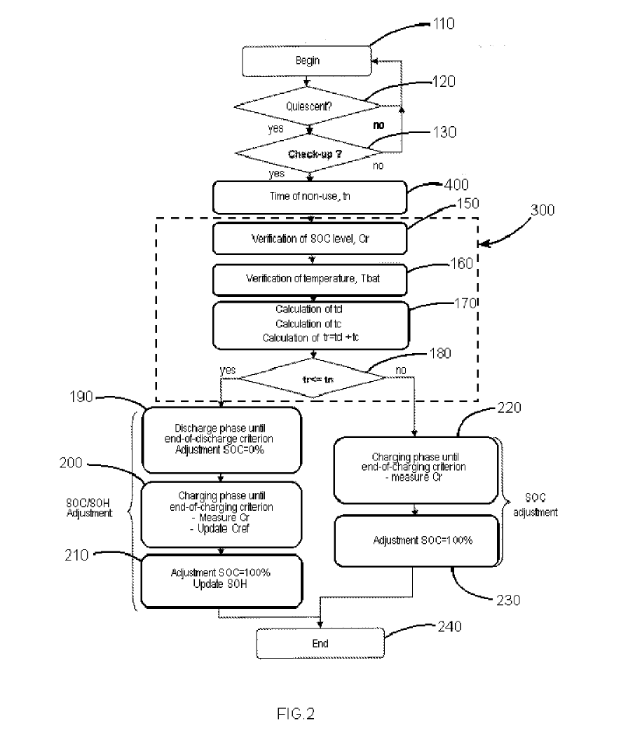

FIG. 2 is a schematic of a mode of execution of a method of operation of a device according to the invention.

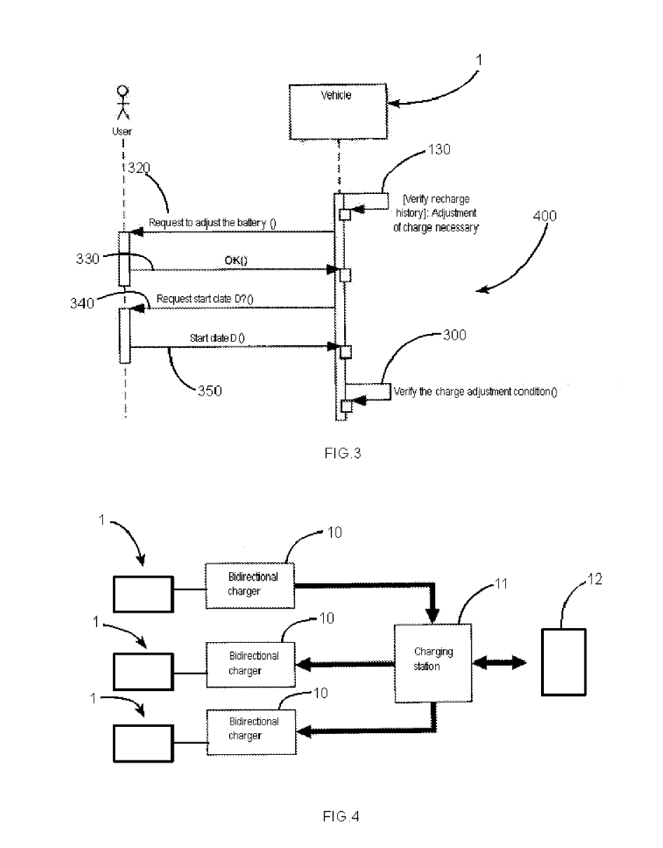

FIG. 3 is a detailed chart representing a procedure of the mode of execution of the method of operation.

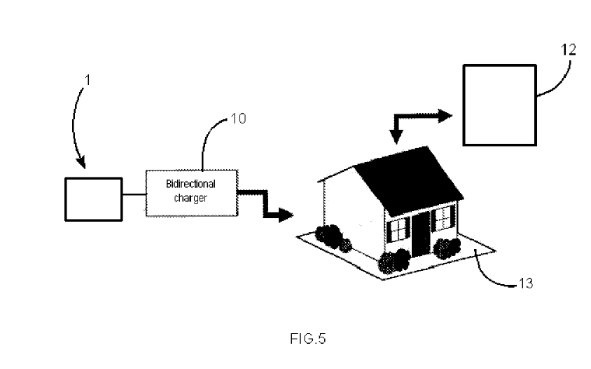

FIG. 4 is a chart illustrating several systems according to the invention, which are linked to a network via chargers.

FIG. 5 is a chart illustrating a system according to the invention, which is linked to a network via a charger and a house.

An embodiment of a system according to the invention is described hereinafter with reference to FIG. 1. The system 1 comprises a device 4 for determining a feature or a value characteristic of a battery 3, a device 9 consuming energy of the battery and the battery 3 supplying the device. The system can be of any nature. It can for example be a portable system such as a telephone or a computer. The system can also be an electric or hybrid automotive vehicle. The device 4 for determining a feature or a feature value can comprise an electronic unit, such as a calculator. The determining device 4 makes it possible in particular to control the connection of the battery to a charger and/or to control the connection of the battery to the consuming device 9. The determining device makes it possible in particular to command controlled breakers ensuring the connections. The determining device preferably comprises a man-machine interface. In this document, the term “feature” is sometimes used for “value of feature”.

The device according to the invention, in particular the electronic unit, comprises hardware and/or software means governing the method of operation according to the invention, that is to say comprising hardware and/or software means for implementing the steps of the method of operation according to the invention. In particular, the hardware and/or software means comprise an element 5 for receiving a request to determine a value characteristic of a battery, an element 6 for determining, by interrogating a user, the next date at which a consuming device 9 will need energy from the battery, an element 7 for verifying that it is possible to determine the value characteristic of the battery by the next date, an element 8 for determining the value characteristic of the battery by carrying out a phase of charging and/or discharging of the battery.

The hardware and/or software means can also comprise an element for detecting a need to determine a value of a feature of the battery, an element for forecasting the energy need of the device, an element for verifying the possibility of determining this value of feature in relation to the forecast energy need of the device, an element for determining the value of the feature of the battery.

The software means can comprise calculator or computer programs. The feature comprises the state of charge and/or the state of health of the battery.

The element 5 for receiving a request to determine a value characteristic of a battery can comprise a receiver of a signal, in particular an electrical signal, containing a request to determine a feature value. This request can be formulated by any device of the system 1, in particular by a device for managing the operation of the battery. Alternatively, the request can be formulated by a device external to the system, in particular a user. In this case, the user can formulate the request with the aid of the man-machine interface.

The element for detecting a need to determine a value of a feature of the battery can comprise a simple time measurement circuit, a detectable signal being emitted by this circuit as soon as a duration greater than a threshold is exceeded since the last implementation of the method, in particular since the last implementation in the course of which the battery was completely discharged and then completely charged. The detection element can complementarily or alternatively comprise an element for detecting a wish or an action of the user, this element being for example a facility of a man-machine interface. The signal emitted by the detection element is received by the element for receiving a request.

The element 6 for determining the next date at which a consuming device 9 will need energy from the battery preferably implements an interrogation of a user. Thus, a signal, for example visual and/or audible, invites the user to indicate to the device the next date at which the consuming device will need to use energy from the battery. “Date” is understood to mean “date” in the broad meaning, that is to say as including the indications of hours, or indeed minutes. The signal is preferably emitted by the man-machine interface. It can consist of the illuminating of an actual or virtual telltale, more generally of any sign appearing on a screen. The user responds to the interrogation by providing the date to the device. This is preferably also done via the man-machine interface, in particular with the aid of an actual or virtual keyboard or any other means for inputting information.

The element 7 for verifying that it is possible to determine the value characteristic of the battery ahead of the next date uses the current date, the above-mentioned date information and an item of information regarding the duration of a phase of determining the feature so as to determine this possibility. The verifying element can comprise calculation means making it possible to determine the battery discharging time, and, optionally to determine the complete battery charging time. The verifying element can comprise an element for comparing the times determined by the calculation means and by the determining element.

In such a case, an element 8 for determining the value characteristic of the battery is implemented. This element controls the implementation of a phase of charging and/or discharging of the battery. The determining element can comprise elements for determining, in particular for measuring, the battery charging and discharge currents. The determining element can also comprise elements for temporal integration of these currents. The determining element can alternatively or complementarily comprise means for detecting end of charging and/or end of discharging of the battery.

The element for forecasting the energy need of the device can comprise an element for interrogating the user and an element for interpreting a response of the user, this element can for example be a facility of a man-machine interface. Complementarily or alternatively, the element 6 for forecasting the energy need of the device can comprise an internal circuit of the device such as a memory containing a programming of the timeslots of use of the device.

On account of the problems of error in the value of the feature, there is proposed a solution for redetermining or adjusting the values of the feature, in particular the values of charge of the battery Cr, of capacity of the battery Cref, of state of charge SOC and of state of health SOH. This solution consists of an implementation of a procedure for determining the value of the feature different from that customarily used, the latter leading to an error after a certain time. This is done periodically or occasionally while complying with several constraints of use of the system and of environment of the latter so as to guarantee management of the battery using correct values of state of charge SOC and/or of state of health SOH.

A mode of execution of a method of operation according to the invention is described hereinafter with reference to FIG. 2.

In a first step 130, a need to determine a value of a feature of the battery is detected. If such is the case, we go to step 300. If such is not the case, we loop over step 110.

Next in a second step 300, the possibility of determining this value of feature in relation to a forecast energy need of the device is verified.

Next, in a third step 190, the value of the feature of the battery is determined, this step comprising a phase of complete discharging of the battery.

In the embodiment represented in FIG. 2, several steps are prior to step 130.

In a more detailed manner, in a step 110, the method is initialized.

Next, in a step 120, a test is carried out to see whether the battery is powering the device. If such is the case, we loop over step 110. If such is not the case, we go to step 130.

Between step 130 and step 300, a step 400 is implemented in which the duration to or the time during which the device will not use or will not need energy from the battery is determined. This step is preferably carried out by interrogating the user.

Step 300 comprises sub-steps 150, 160, 170 and 180.

In sub-step 150, the value of state of charge and/or the value of charge of the battery is determined. Indeed, it is possible to condition the rest of the method to values of state of charge or of charge of the battery.

In sub-step 160, the temperature of the battery is determined. Indeed, it is possible to condition the rest of the method to a value of temperature of the battery.

In sub-step 170, the duration td necessary for the complete discharging of the battery and the duration tc necessary for the complete charging of the battery are determined. Finally, the total duration tr of implementation of the method is calculated with total discharging of the battery then total recharging of the battery, with tr=td+tc.

In sub-step 180, a test is carried out to see whether it is possible to implement a step of complete discharging of the battery and then a step of complete charging of the battery, for example, a test is carried out to see whether the duration tr is less than the duration tn. If such is the case, we go to a step 190. If such is not the case, we go to a step 220. Quite obviously, it is possible to take account of the fact that it will not always be necessary for the battery to be completely recharged when the user needs to use the consuming device again.

In step 190, the battery is discharged completely, that is to say until an end-of-discharging criterion is satisfied. At the end of the discharging step, its state of charge SOC therefore equals 0%. This state-of-charge value is therefore updated in the battery management system.

Next, in a step 200, the battery is charged completely, that is to say until an end-of-charging criterion is satisfied. During this step, the capacity and therefore the charge transmitted to the battery are determined. Accordingly, it is for example possible to determine, in particular to measure, the battery charging current throughout the step. This makes it possible to determine the capacity Cr and to update Cref of the battery.

Next, in a step 210, given that the battery is completely charged, its state of charge SOC therefore equals 100%. The capacity Cr of the battery equals the available actual capacity Cref. The state-of-charge value is therefore once again updated in the SOC battery management system. Moreover, it is then possible to update the value of state of health SOH, for example by calculating Cref/Cref0.

Thereafter we go to an end step 240.

In step 220, the battery is charged completely, that is to say until an end-of-charging criterion is satisfied.

In step 230, the battery is completely charged, its state of charge SOC therefore equals 100%. The state-of-charge value is therefore once again updated in the SOC battery management system.

Thereafter we go to an end step 240.

In a step 400 described hereinafter with reference to FIG. 3 and following step 130, there may be a dialogue with a user of the device, for example via the man-machine interface of the device.

In a first sub-step 320, the device asks the user if he wants to implement the procedures making it possible to adjust or to redetermine features of the battery.

In a sub-step 330, the user responds to the device.

In a sub-step 340, the device asks the user to indicate to it the duration during which he will not use the device or the point in time at which he will recommence using the device.

In a sub-step 350, the user responds to the device. In both cases, the device can therefore determine the duration to during which the user ought not to use the device.

The method proposes an adjustment of Cr and of Cref by taking into account several constraints such as:
constraint of use of the device or system by the user,
time of non-use and time of use of the device or system,
in the case of an electric vehicle: desired distance to be traveled Dap,
regular or else occasional diagnosis according to the desire of the user or the technological or safety constraints of the device,
environmental constraints,
charging capacity remaining Cr,
temperature of the battery Tbat,
type of charging and/or discharging system.

The threshold of remaining charging capacity to determine the adjustment condition is dynamic as a function of various constraints mentioned hereinabove. It is preferred for example to perform the adjustment when the charge of the battery is already sufficiently low, thereby avoiding having to discharge almost the whole of the battery, or indeed the whole of the battery.

The method is preferably applied during phases wherein the user desires to recharge the battery, for example for an automotive vehicle during the night or else at the charging station during work.

A command to launch the method can be proposed in the menu of the man-machine interface of the system for managing the operation of the device or of the battery. The user can thus launch the method on his own initiative.

The calculation of the discharging time td mentioned above takes into account the features of the discharging means of the charging system, the remaining capacity of the battery and the temperature of the battery.

The calculation of the charging time tc to attain complete charging takes into account the features of the charging means of the charging system, the charging capacity of the battery and the temperature of the battery.

This method according to the invention is valid for all battery technologies.

FIG. 4 illustrates the method according to the invention applied to automotive vehicles 1 situated at the level of a charging station 11 linked to an electrical network 12, such as the commercial electrical network and comprising several chargers 10, in particular bidirectional chargers. Thus, when it is decided to discharge the battery of one of the vehicles, the energy of this battery can be used to charge one or more batteries of other vehicles linked to the charging station or can be fed into the network. This choice can be made according to the presence or the absence of other vehicles connected to the station.

The discharging phase can be fast (about 30 minutes) or slow (about 2 hours) depending on the bidirectional charger used. During the charging phase, the charging time is in general 8 hours for a 3 kW slow charging system, 4 hours for a 6 kW medium charging system and 30 minutes for a 48 kW charging system.

FIG. 5 illustrates the method according to the invention applied to an automotive vehicle 1 situated at the level of a residence 13 linked to an electrical network 12, such as the commercial electrical network and comprising a charger 10, in particular a bidirectional charger. The user can hook his vehicle up to the electrical system of the residence. As soon as the method is launched, the battery of the electric vehicle is discharged during the discharging phase. The energy can be used for general consumption in the residence or else can be fed into the network.

As emerges from the above account, the method and the device according to the invention make it possible to determine an actual value of a feature as opposed to an estimated, calculated, value of this feature. The method for determining an actual value of a feature makes it possible to determine with good accuracy the value of the feature, at a given instant and under predefined conditions of operation of the battery, in contradistinction to estimation procedures which make it possible to calculate an instantaneous value by implementing calculation algorithms on the basis of measurements of physical quantities, for example the voltage of the battery. The estimated values may turn out to be somewhat inaccurate as a function in particular of the conditions of use of the battery and of its aging.

This actual value, determined at a given instant, can advantageously be used to adjust a procedure for estimating the feature value or used in a procedure for estimating the value, so as to avoid drifts over time of these estimation procedures.

Advantageously, as seen previously, it is possible to use the actual value previously determined for a feature of state of charge SOC of the battery, to reinitialize or adjust the procedure for estimating the state of charge.

Advantageously also, at least one value of the state of health SOH of the battery or the capacity Cref of the battery is saved in a memory. Thus, after determination of the actual value of the state of health SOH of the battery or of the capacity Cref of the battery, this actual value is recorded in the said memory. Consequently, at each implementation of the estimation procedure, the value recorded in memory can be used. For example, this value can be used as a constant in a mathematical formula expressing the value of the state of health SOH of the battery or of the capacity Cref of the battery as a function of various measured or estimated parameters.

1. Method of operation of a device for determining a feature of a battery from among the state of charge of the battery, the state of health of the battery and the capacity of the battery, the device comprising a man-machine interface, the method comprising the following steps:
Receiving a request to determine an actual value of the feature of a battery,
Determining, by interrogating a user via the man-machine interface, the next date at which a consuming device will need energy from the battery,
Verifying that it is possible to determine the actual value of the feature of the battery by the next date,
If such is the case, determining the actual value of the feature of the battery by carrying out a phase of charging and/or discharging of the battery.

2. Method of operation according to claim 1, which comprises the following step:
Using the previously determined actual value for the said feature of the state of charge of the battery, to reinitialize or adjust a procedure for estimating, in particular for estimating the value of the state of charge of the battery.

3. Method of operation according to claim 1, wherein the feature is the state of health of the battery or the capacity of the battery, wherein at least one value of the said feature is saved in a memory and wherein, after determination of the actual value of the feature, the actual value is recorded in the memory.

4. Method of operation according to claim 1, wherein the step of determining the actual value of the feature of the battery comprises a phase of discharging the battery, and then a phase of charging of the battery.

5. Method according to claim 1, wherein the step of determining the actual value of the feature of the battery comprises a phase of complete charging of the battery.

6. Method according to claim 5, wherein the intensity of the battery charging current is determined throughout the battery charging phase and this intensity is used to determine the level of the charge of the battery at the end of the charging phase.

7. Method according to claim 1, wherein the step of determining the actual value of the feature of the battery comprises a phase of complete discharging of the battery.

8. Method according to claim 1, wherein the intensity of the battery discharge current is determined throughout the battery discharging phase and the intensity is used to determine the level of the charge of the battery at the end of the discharging phase.

9. Method according to claim 1, wherein the step of receiving a request to determine an actual value of the feature of the battery comprises the detection of a deadline of a time delay triggered during a previous determination step and/or a detection of a wish for determination expressed by the user of the device.

10. Method according to claim 1, wherein the step of verifying that it is possible to determine the actual value of the feature of the battery by the next date at which a consuming device will need energy from the battery comprises a validation confirming that the device is not forecast to use energy from the battery for a duration at least equal to the duration of the step of determining the actual value of the feature of the battery.

11. Method according to claim 1, wherein the energy arising from the battery during the discharging of the battery is:
used to recharge at least one other battery; and/or
used in a residence to which the device is electrically connected; and/or
fed into an electrical network.

12. Data recording medium readable by a calculator on which is recorded a computer program comprising software means for implementing the steps of the method according to claim 1.

13. Device for determining a feature of a battery from among the state of charge of the battery, the state of health of the battery and the capacity of the battery, the device comprising:
a man-machine interface, and
hardware and/or software elements for implementing the steps of the method according to claim 1.

14. Device according to claim 13, wherein the hardware and/or software elements comprise:
An element for receiving a request to determine an actual value of the feature of a battery,
An element for determining, by interrogating a user, the next date at which a consuming device will need energy from the battery,
An element for verifying that it is possible to determine the actual value of the feature of the battery by the next date,
An element for determining the actual value of the feature of the battery by carrying out a phase of charging and/or discharging of the battery.

15. System comprising a device according to claim 13, a battery and a consuming device.

16. System comprising a device according to claim 14, a battery and a consuming device.

17. Automotive vehicle comprising a device according to claim 13, a battery and a consuming device.

18. Automotive vehicle comprising a device according to claim 14, a battery and a consuming device.

19. Method according to claim 2, wherein the procedure for estimating the value of the state of charge of the battery is a procedure for estimating in real time the value of the state of charge of the battery.

20. Method according to claim 11, wherein the energy arising from the battery during the discharging of the battery is fed into the commercial electrical network.
